(19) United States
(12) Patent Application Publication
(10) Pub. No.: US 2024/0316598 A1
(43) Pub. Date: Sep. 26, 2024

(54) COMPRESSION GAP CONTROL FOR PAD-BASED CHEMICAL BUFF POST CMP CLEANING

(71) Applicant: Applied Materials, Inc., Santa Clara, CA (US)

(72) Inventor: Clinton P. SAKATA, Santa Clara, CA (US)

(21) Appl. No.: 18/123,746

(22) Filed: Mar. 20, 2023

(51) Int. Cl. B08B 1/00; B08B 1/02; B08B 13/00; B24B 37/20

(52) U.S. Cl. CPC B08B 1/10; B08B 1/20; B08B 13/00; B24B 37/20; H01L 21/67219

(57) ABSTRACT

Embodiments of the disclosure include an apparatus and method of cleaning a substrate. A method of cleaning a substrate, includes rotating, a substrate table by first motor, delivering a fluid to a surface of a substrate positioned on a supporting surface of the substrate table of a cleaning module, rotating a cleaning pad at a cleaning speed, and sensing an initial torque value generated by a second motor with a controller, lowering the cleaning pad with a lift actuator assembly until the controller senses a contact torque generated by the second motor. The contact torque is when a pad processing surface of the cleaning pad contacts a surface of the substrate at a contact point. The method includes translating the cleaning pad a cleaning distance towards the substrate by a command from the controller. The cleaning pad is compressed by the translation of the cleaning pad the cleaning distance. The pad processing surface of the cleaning pad is then translated across the substrate supporting surface.

### BACKGROUND

### Field

Embodiments described herein generally relate to equipment used in the manufacturing of electronic devices, and more particularly, to a cleaning module which may be used to clean the surface of a substrate in a semiconductor device manufacturing process.

### Description of the Related Art

Chemical mechanical polishing (CMP) is commonly used in the manufacturing of high-density integrated circuits to planarize or polish a layer of material deposited on a substrate. In a pre-clean module used in a CMP process, a rotating cleaning pad is pressed against a material layer on a surface of the substrate, and material is removed across the material layer through a combination of chemical and mechanical activity provided by a polishing fluid and relative motion of the cleaning pad and the substrate. Conventional cleaning pads can scratch the surface of substrates because the force applied is too great and particles of a polishing slurry become embedded within the cleaning pad, scratching the substrate surface.

Therefore, there is a need for systems and methods for polishing surfaces that are susceptible to scratches.

### SUMMARY

In some embodiments, a method of cleaning a substrate, includes rotating, a substrate table by first motor, delivering a fluid to a surface of a substrate positioned on a supporting surface of the substrate table of a cleaning module, rotating a cleaning pad at a cleaning speed, and sensing an initial torque value generated by a second motor with a controller, lowering the cleaning pad with a lift actuator assembly until the controller senses a contact torque generated by the second motor. The contact torque is when a pad processing surface of the cleaning pad contacts a surface of the substrate at a contact point. The method includes translating the cleaning pad a cleaning distance towards the substrate by a command from the controller. The cleaning pad is compressed by the translation of the cleaning pad the cleaning distance. The pad processing surface of the cleaning pad is then translated across the substrate supporting surface.

In some embodiments, a pre-clean module for cleaning a substrate includes a rotatable substrate table. The rotatable substrate table includes a substrate supporting surface for supporting a substrate thereon. The pre-clean module also includes a pad carrier assembly. The pad carrier assembly includes a carrier column, a carrier arm coupled to the carrier column, extending radially outward from an axis of the carrier column, a lift mechanism coupled to the carrier arm, a lift actuator assembly coupled to the carrier arm and in mechanical communication with the lift mechanism, and a pad carrier configured to be raised and lowered by the lift mechanism and the lift actuator assembly with respect to the surface of the substrate table. The pad carrier includes a cleaning pad, a pad motor configured to rotate the cleaning pad about a central motor axis, and a shaft that couples the pad motor to the cleaning pad. The pre-clean module also includes a system controller configured to determine a pad compression.

In yet another embodiment, a pre-clean module includes a rotatable substrate table. The rotatable substrate table includes a substrate supporting surface for supporting a substrate thereon. The pre-clean module also includes a system controller configured to calculate a force applied to a pad based on a compression of a pad, and pad carrier assembly. The pad carrier assembly includes a carrier arm, a lift mechanism coupled to the carrier arm, a lift actuator assembly coupled to the carrier arm and in mechanical communication with the lift mechanism. The lift actuator assembly is configured to apply less than 30 N and is controlled by the system controller. The pre-clean module also includes a pad carrier configured to be moved by the lift mechanism and lift actuator assembly. The pad carrier includes a pad motor capable of sensing and communicating a real time experienced torque value, a shaft, and a pad coupled to the pad motor by the shaft, the pad comprising a PVA material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic plan view of an exemplary chemical mechanical polishing (CMP) processing system, which uses a pre-clean module described herein, according to one or more embodiments.

FIG. 2 is an isometric view of one side of an exemplary pre-clean module according to one or more embodiments.

FIG. 3A is a side sectional view of an angled embodiment of a pad carrier positioning arm, according to one or more embodiments.

FIG. 3B is a top sectional view of an angled embodiment of the pad carrier positioning arm, according to one or more embodiments.

FIG. 3C is a front view of an angled embodiment of the pad carrier positioning arm, according to one or more embodiments.

FIG. 3D is a detailed view of an angled embodiment of the pad carrier positioning arm, according to one or more embodiments.

FIG. 4A is a view of features of formed on processing surface of a cleaning pad processing surface, according to one or more embodiments.

FIG. 4B is a view of features of formed on processing surface of a cleaning a pad processing surface, according to one or more embodiments.

FIG. 5 is a flow diagram for cleaning a pad processing surface, according to one or more embodiments.

FIG. 6 is a graph illustrating the Stribeck curves to relate friction of hydrodynamic bearings to a Hersey number.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to equipment used in the manufacturing of electronic devices, and more particularly, to a chemical-mechanical buff, also known as a pre-clean (PC) module which may be used to clean the surface of a substrate during a portion of a semiconductor device manufacturing processing sequence.

During a cleaning process performed in the PC module, a surface of a cleaning pad formed of a polyvinyl alcohol (PVA) material provides a shear force across the surface of a substrate that is to be cleaned. The cleaning pad is used to remove scratches and residue from the surface of the substrate due to the properties of the cleaning pad material, such as the pad material's mechanical strength and abrasion resistance. However, PVA material is water absorbent, soft, and elastic, in addition to typically being provided in a thicker and larger form factor than other conventional CMP polishing pads. Thus PVA tends to hold onto particulate matter and thereby cause scratches to be formed on the surface of the substrate under some processing conditions.

In the embodiments described herein, a PC module is adapted to apply a fluid absorbent cleaning pad at a lower down force, and rotate the pad at a high rotational speed to form a hydrodynamic film there between as the cleaning pad translates across the surface of the substrate, while measuring or determining the amount of down force. In some embodiments, the down force can be inferred by the measurement of pad compression caused by an actuator coupled to a pad carrier coupled to the cleaning pad.

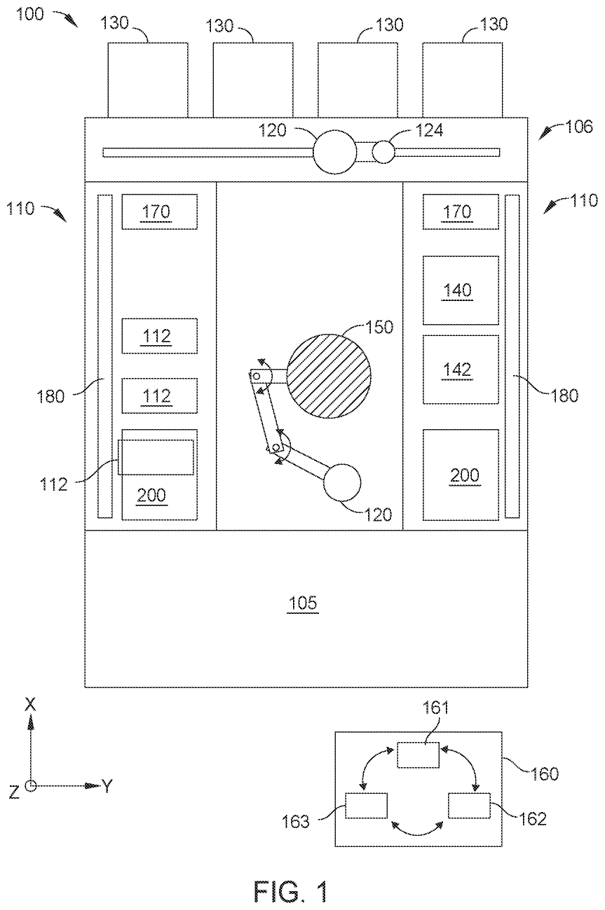

FIG. 1 is a schematic plan view of an exemplary chemical mechanical polishing (CMP) processing system 100, which uses a pre-clean (PC) module 200 described herein, according to one or more embodiments. In FIG. 1, certain parts of the housing and certain other internal and external components are omitted to more clearly show the PC module within the CMP processing system 100. Here, the CMP processing system 100 includes a first portion 105 and a second portion 106 coupled to the first portion 105 and integrated therewith. The first portion 105 is a substrate polishing portion featuring a plurality of polishing stations (not shown).

The second portion 106 includes one or more post-CMP cleaning systems 110 including a plurality of system loading stations 130, one or more substrate handlers, e.g., a first robot 124 and a second robot 150, a plurality of modules or stations, 112, 140, 142, 170 and, PC modules 200. In some embodiments the one or more cleaning systems 110, includes a location specific polishing (LSP) module 142, a metrology station 140, vertical cleaning modules 112, a drying unit 170, and/or a substrate handler 180. The PC module 200 is configured to process a substrate 120 disposed in a substantially horizontal orientation.

The first robot 124 is positioned to transfer substrates 120 to and from the plurality of system loading stations 130, e.g., between the plurality of system loading stations 130 and the second robot 150 and/or between the post-CMP cleaning system 110 and the plurality of system loading stations 130. In some embodiments, the first robot 124 is positioned to transfer the substrate 120 between any of the system loading stations 130 and a processing system positioned proximate thereto. For example, in some embodiments, the first robot 124 may be used to transfer the substrate 120 between one of the system loading stations 130 and the metrology station 140.

The second robot 150 is used to transfer the substrate 120 between the first portion 105 and the second portion 106. For example, here the second robot 150 is positioned to transfer a to-be-polished substrate 120 received from the first robot 124 to the first portion 105 for polishing therein. The second robot 150 is then used to transfer the polished substrate 120 from the first portion 105, e.g., from a transfer station (not shown) within the first portion 105, to one of the PC modules 200 and/or between different stations and modules located within the second portion 106. Alternatively, the second robot 150 may transfer the substrate 120 from the transfer station within the first portion 105 to one of the plurality of modules or stations, 112, 140, 142, 170, 200. Here, each PC module 200 is disposed within the second portion 106 in a location proximate to the first portion 105.

Typically, the PC module 200 receives a polished substrate 120 from the second robot 150 through a first opening (not shown) formed in a side panel of the PC module 200, e.g., though a door or a slit valve disposed in the side panel. The substrate 120 is received in a horizontal orientation by the PC module 200 for positioning on a horizontally disposed substrate support surface therein. The PC module 200 then performs a pre-clean process, such as a cleaning or buffing process, on the substrate 120 before the substrate 120 is transferred therefrom.

In some embodiments, operation of the CMP processing system 100, is directed by a system controller 160. The system controller 160 includes a programmable central processing unit (CPU) 161 which is operable with a memory 162 (e.g., non-volatile memory) and support circuits 163. The support circuits 163 are conventionally coupled to the CPU 161 and comprise cache, clock circuits, input/output subsystems, power supplies, and the like, and combinations thereof coupled to the various components of the CMP processing system 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the CMP processing system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 160 may be used with one or any combination of the various modular polishing systems described herein and/or with the individual polishing modules thereof.

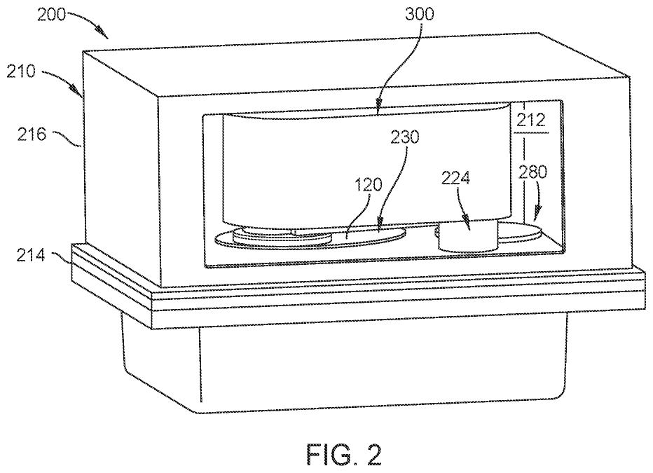

FIG. 2 is an isometric view of an exemplary PC module 200 which may be used in the CMP processing system 100 described herein. In FIG. 2, a portion of a lid 216 is omitted to more clearly show the internal components of the PC module 200.

In some embodiments, the PC module 200 includes a chamber 210 having a basin 214, and a lid 216, formed of a plurality of side panels, which collectively define a processing area 212. The lid 216 may be removable for general maintenance. The processing area 212 of the PC module 200 further includes a rotatable substrate table 230, a pad conditioning station 280, and a pad carrier assembly 300 coupled to a rotatable carrier column 224. The pad carrier assembly 300 is movable between at least a first position over the substrate 120 and a second position over the pad conditioning station 280. The rotatable substrate table is connected to a table motor (not shown) that rotates the substrate table 230.

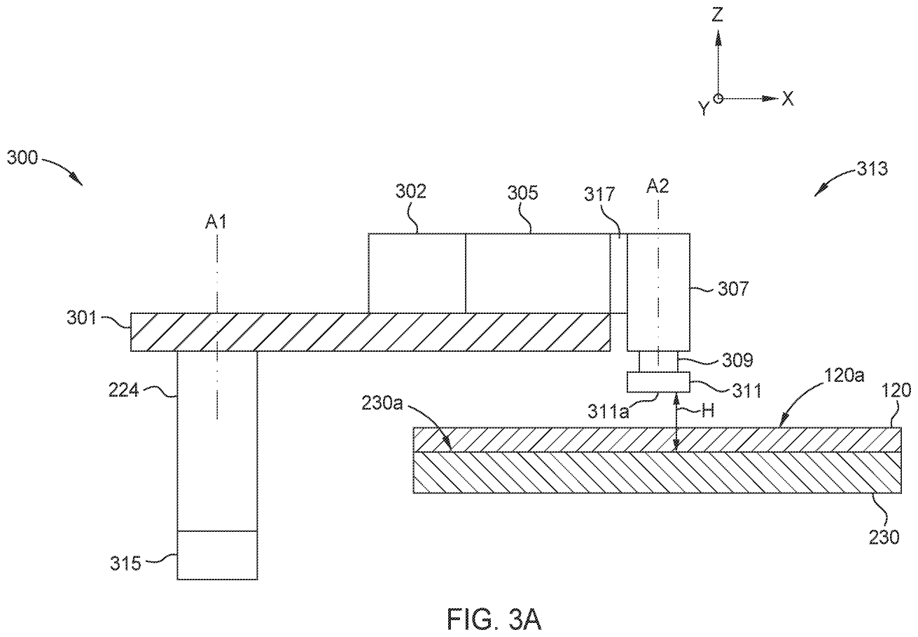

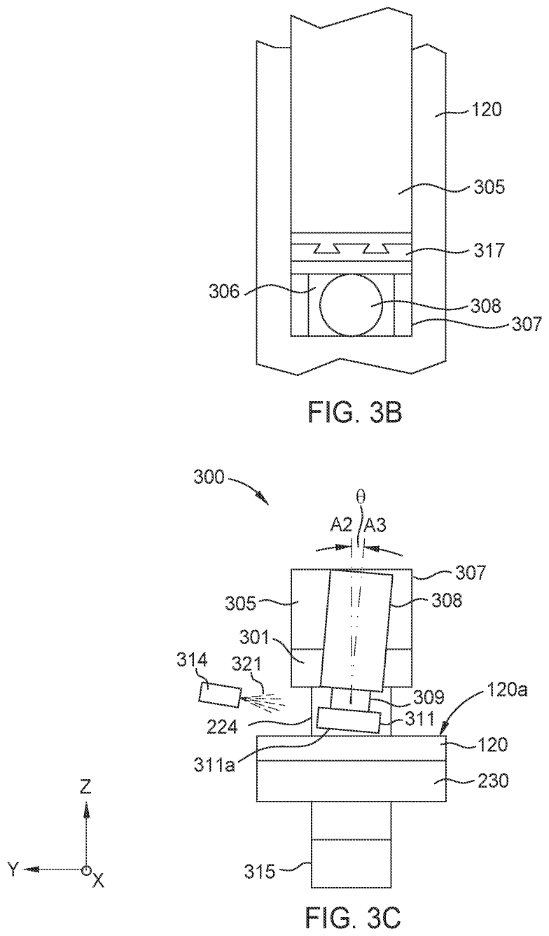

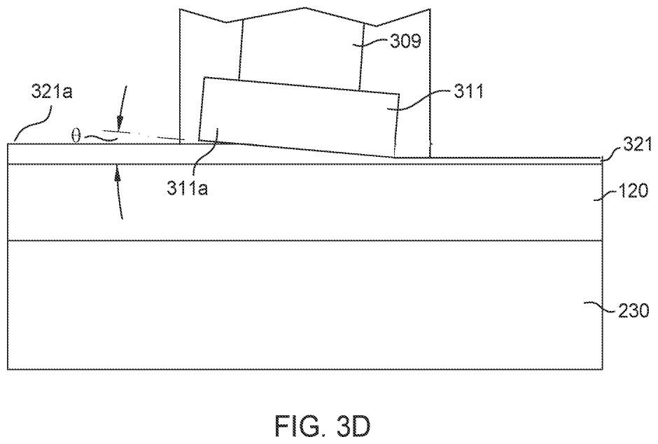

FIG. 3A is a side sectional view of an exemplary pad carrier assembly 300 which may be used in the PC module 200 of FIG. 2. The pad carrier assembly 300 includes a carrier arm 301 coupled to the carrier column 224 extending radially outward from a column axis A1, and disposed above the substrate table 230. The pad carrier assembly 300 is rotated between its positions by a column motor 315. The pad carrier assembly 300 also includes a lift actuator assembly 302 and a lift mechanism 305 driven by the lift actuator assembly 302. The lift actuator assembly 302 and lift mechanism 305 may operate in combination to raise and lower a pad carrier 307 closer to and away from the substrate table 230. The lift mechanism 305 enables the pad carrier 307 to have a travel distance between about 5 mm to about 15 mm, for example 10 mm. The lift actuator assembly 302 and lift mechanism 305 may enable to pad carrier 307 to produce a force between about 0.01 lbf (0.04N) to 10 lbf (44.5N), for example about 6.7 lbf (30N), along the Z axis. The lift mechanism 305 may include at least, a hard-stop, a ball screw assembly, a lead screw assembly, and/or a displacement sensor. The lift mechanism 305 is connected to a linear rail assembly 317. The linear rail assembly 317 mechanically connects the lift mechanism 305 to the movable pad carrier 307. The movable pad carrier 307 is further coupled and connected to a cleaning pad 311 via a shaft 309. The linear rail assembly 317 may keep the motion of the pad carrier 307 perpendicular to the substrate 120 and allow the pad carrier 307 to be connected to the linear rail assembly 317 at various angles relative to a vertical direction along a vertical axis A2, aligned with the linear rail 317 and the Z axis. The lift actuator assembly 302 can include a motor or actuator, such as an electric, pneumatic, and/or hydraulic motor or actuator that is coupled to the lift mechanism 305 using a direct drive, belt and pulley, pneumatic, and/or hydraulic configuration.

As shown in FIG. 3A, the vertically movable pad carrier 307 is disposed on a distal end 313 of the carrier arm 301. The pad carrier 307 supports the cleaning pad 311 above the substrate 120. The pad carrier 307, the lift mechanism 305, and the lift actuator assembly 302 are all in mechanical communication to create the movement of the pad carrier 307 along the linear rails 317 relative to the surface of the substrate 120a. The pad carrier 307 is coupled to the pad 311 by the shaft 309. In some embodiments, the pad carrier 307 is sized to support a cleaning pad 311 having a diameter of between about 20 mm and 150 mm, such as between about 70 mm and 130 mm, such as about 120 mm. In some embodiments, the pad carrier positioning arm 301 supports a larger cleaning pad 311 compared to conventional pre-clean modules. The cleaning pad 311 may include a polyvinyl alcohol (PVA) material according to some embodiments, but other materials are contemplated. In some embodiments, the carrier arm 301, the lift actuator assembly 302, the lift mechanism 305, the pad carrier 307, and the shaft 309 are made from materials comprising metals, including stainless steel, but other materials are contemplated to achieve a desired weight, vibration characteristics, and corrosive resistant characteristics. A height H defines a distance between a pad processing surface 311a and the substrate supporting surface 230a. The height H is adjusted by the lift actuator assembly 302 and the lift mechanism 305 and may be calculated and controlled by the system controller 160. As will be discussed further below, during processing it has been determined that by controlling the distance traveled (e.g. a cleaning distance), the distance that the cleaning pad 311 is engaged or compressed against the surface of the substrate 120a after the cleaning pad 311 comes into contact with the surface of a substrate 120a during a downward motion of the pad carrier 307, the more accurately and consistently the contact force (i.e., down force) and overall pre-clean process results can be controlled.

It has been found that variations in the cleaning pad mechanical properties over time or from properties from cleaning pad to cleaning pad, and also friction inherent within the system (e.g., friction within the lift mechanism 305 and linear rails 317), can greatly affect the ability of the pre-clean module to consistently control the contact force created between the pad processing surface 311a and the substrate surface 120a, especially when low contact forces (e.g., <10 Newtons (N)) are required during a pre-cleaning process. However, it has been found that the accuracy of the height H dimension can be controlled to a to increments as small as about 10 μm to about 40 μm and with position repeatability of +4 μm by use of, for example, a ball-screw actuator, linear rail slides and closed-loop sensing techniques with the system controller (e.g., control the position by use of encoders). In some embodiments, a high level of accuracy and precision enables the pressure exerted on the substrate 120 by the cleaning pad 311 to be more accurately determined than a pressure sensor alone.

FIG. 3B illustrates a top down view of a portion of the pad carrier assembly 300 according to some embodiments. As shown, the pad carrier 307 includes a pad motor 308 and frame 306 to support and attach the pad carrier 307 to the linear rails 317. The frame 306 may include any structural material that can be used to attach to the linear rails 317 and hold a pad motor 308. The pad motor 308 rotates the cleaning pad 311 about the central motor axis A3. In one example, the pad motor 308 can rotate the pad 311 at a cleaning speed between about 150 RPM to about 4500 RPM, for example about 250 RPM to about 1500 RPM, in yet another example about 750 RPM to about 2500 RPM. The pad motor 308 is capable of sensing and communicating a real time experienced torque values. The pad carrier 307 also includes a frame 306 comprising a metal bracket with side supports that resist flexing during cleaning operations and a lower plate configured to support and/or secure the pad motor 308. In some embodiments, the pad motor 308 of the pad carrier 307 may be mounted to the linear rails 317 at different orientation angles θ (see, e.g., FIGS. 3C and 3D). Not being bound by theory, the different angles allow the cleaning pad 311 and pad processing surface 311a to achieve a controlled amount of contact area on the substrate surface 120a. The pad motor 308 may be capable of rotating the cleaning pad 311 between about 500 RPM to about 3000 RPM, for example 1500 RPM.

FIG. 3C is a front side sectional view of an exemplary pad carrier assembly 300 illustrating the pad motor 308 of the pad carrier 307 attached to the lift mechanism 305 at an angle θ. The pad carrier 307 may be attached to the linear rails 317 at an angle theta (θ) so that the pad carrier 307 motion will be vertical along the axis A2, but a pad processing surface 311a of the cleaning pad 311 is not co-planar with a substrate surface 120a. For example, the central motor axis A3 may be disposed at an angle θ relative the vertical axis A2 and thus is not aligned with the motion direction of the linear rails 317. The pad carrier assembly 300 may also include a fluid nozzle 314 that is disposed near the pad carrier 307. The fluid nozzle 314 is configured to spray a fluid 321 onto the substrate 120. The pad carrier assembly 300 may include one or more fluid nozzles 314 depending on the operation requirements of a pre-cleaning process. In some embodiments, there may be multiple nozzles 314, where some nozzles 314 are coupled to the carrier arm 301 and some nozzles 314 are not. According to some embodiments, the pad carrier 307 is maintained at an angle θ, which is defined as the angle between the vertical axis A2 and the motor axis A3. According to some embodiments, the pad processing surface 311a may be aligned with the XY plane. In other embodiments, the pad processing surface 311a is angled from the XY plane by the angle θ. In some embodiments, the angle θ is greater than zero and up to about 45° from the XY plane, for example between about 1° and about 10°, for example about 5°. It is believed that when the cleaning pad 311 is angled relative to the surface of the substrate 120a, the cleaning pad 311 is able to better recharge itself with fluid 321 compared to when the pad processing surface 311a is positioned parallel to the substrate surface 120a.

During processing, the fluid 321 provided by the nozzles 314 may include a polishing fluid, cleaning liquid, and/or cleaning solution. For example, the fluid 321 may include one or more of DI water, acids, bases, aqueous based slurry compositions, chelating agents or other useful cleaning fluids. The nozzle(s) 314 may be configured to provide a liquid, a mist or other form of the fluid 321 to the substrate 120 and substrate table 230.

Conventional pad carrier assemblies typically rely on a pressure sensor to determine pressure asserted by a cleaning pad, but it has been shown that pressure sensors are not as accurate when used with elastic materials, such as the material of the cleaning pad. For example, a pressure sensor may only be accurate to +/−0.4 psi. The embodiments described herein are able to measure pressure by using the change in height H to determine the amount of compression of the cleaning pad 311 and then use the height data to more accurately control the amount of pressure applied to the surface of the substrate. Changes in distance traveled are measured much more accurately than changes in pressure and can be derived from at least a sensor in the lift actuator assembly 302 coupled to the lift mechanism 305, and/or the lift mechanism 305. A sensor in the lift actuator assembly 302 and/or the lift mechanism 305 may be a displacement sensor to provide feedback, however position is controlled by the controller 160. In some embodiments, the controller 160 will have at least two control loops to check the position of the pad during an operation. The embodiments described herein are capable of measuring changes in height H with the accuracy and precision as small as +/−10 microns to about +/−40 microns and able to determine an applied pressure as low as 0.04 psi using a compression reference with an accuracy of +/−0.01 psi. For example, a pad diameter of less than about 150 mm, pressures as low as 0.04 psi can be achieved. When the pad 311 is compressed by the lift actuator assembly 302 and lift mechanism 305, a precise pressure value can be determined using a compression reference (e.g. look-up in a data table of calculated compression ˜pressure relations) instead of a pressure sensor alone. The change from the conventional design yields the surprising benefit of being able to accurately and repeat-ably apply pressures as low as 0.04 psi, which can be on the order of a desired applied cleaning pad pressure used in or controlled to during a pre-clean chamber cleaning process. The improvements are discussed further below.

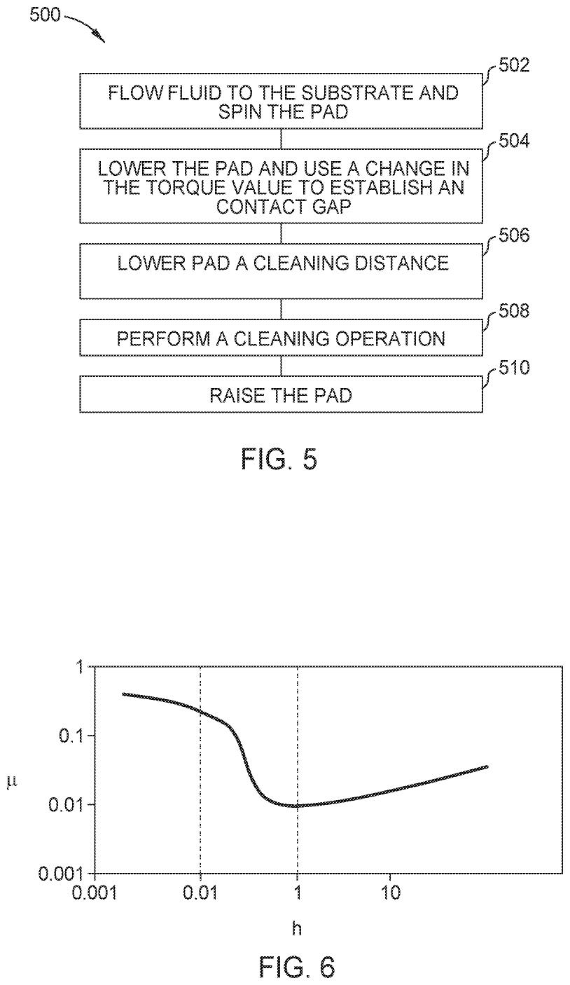

FIG. 3D illustrates a detailed view of the interaction between at least the pad 311, the fluid 321 (e.g., solution dispensed from the nozzle 314) and the surface 120a of the substrate 120. Discussed below with respect to FIGS. 5 and 6, the interaction may be characterized by a Hersey number. For example, a Hersey number greater than 1 is used to create a hydrodynamic film between the cleaning pad and the surface of the substrate when the fluid 321 is provided. This hydrodynamic film helps clean the surface of the substrate 120a.

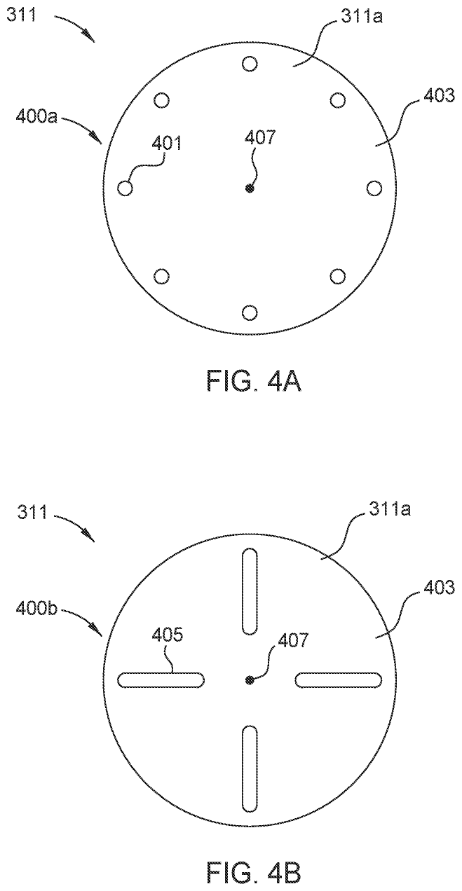

FIGS. 4A and 4B illustrate embodiments of the cleaning pad 311 where the pad processing surface 311a has different pad patterns 400a, 400b according to some embodiments. As shown in FIG. 4A, the pad processing surface 311a may have a base surface 403 with polishing features 401 located radially around the pad center 407. In some embodiments, the features 401 are round raised bosses or radial mesas, as illustrated in FIG. 4A. The features 401, for example, may be elevated to between about 1 mm and about 10 mm from the base surface 403. In another embodiment, the features 401 may be recessed to between about 1 mm to about 10 mm from the base surface 403. Further, the features 401, may include diameters between about 1 mm to about 150 mm, for example 5 mm to 20 mm. While illustrated as round, the features 401 may also be squares, triangles, or other shapes. Further, the features 401 can also be located in other patterns, for example a swirl, spiral, random, and/or linear arrangement.

As illustrated in FIG. 4B, according to some embodiments, the pad processing surface 311a may have a plurality of polishing features comprising spokes (e.g., pencil shapes) 405, arranged in a radial spoke pattern around the center 407 of the pad 311. In one embodiment, the spokes 405 may be elevated about 1 mm to about 10 mm in relation to the base surface 403. In another embodiment, the spokes 405 may be recessed about 1 mm to about 10 mm in relation to the base surface 403. As shown, the pad 311 has a pattern that includes four spokes 405, but in other embodiments, the pad 311 may have fewer or more spokes 405, e.g., from 1 to about at least 12 spokes 405. The spokes 405 can be equal in radial length or they may vary. For example, the spoke 405 may be centered between the pad center 407 and the radially distant edge of the pad 311, and may further be between about 10 mm to 60 mm for example 40 mm.

Benefits of the pad carrier assembly 300 include higher accuracy and precision regarding force and pressure readings through the use of position control are better able to repeatably control the amount of pressure applied to the substrate when low down forces are required during a cleaning process. It has been found that a pressure sensor alone is not accurate enough during the use of elastic cleaning pads at low down forces to generate consistent cleaning pad contact pressures.

### Torque-Position

The controller 160 is configured to analyze at least three motor torque values at different times during a typical cleaning process, which can include an initial torque value, a contact torque value, and a cleaning torque value. The initial motor torque is created when the pad motor 308 causes the cleaning pad 311 to freely spin above the substrate, since the cleaning pad 311 is not in contact with the surface of the substrate 120. The contact torque is created when the pad 311 comes into contact with the cleaning pad 311, but the pad 311 has not been significantly compressed. The cleaning torque value is the motor torque created by the pad motor 308 after the pad 311 has been driven a distance into the substrate 120.

For example, while the pad 311 is rotating and being lowered to contact the substrate 120, the controller 160 is monitoring the load on the pad motor 308 in terms of torque. Once the controller 160 reads a change in torque from the initial torque, to an increase in torque from the pad 311 contacting the substrate 120, a contact torque value is established. The contact torque value indicates that the pad 311 has made contact with the substrate, but the pad has not yet been significantly compressed. The pad 311 is then driven a cleaning distance into the substrate 120 and a cleaning torque is analyzed for process monitoring.

### Pressure-Distance

It has been found that by controlling the position of the cleaning pad 311 relative to the surface of the substrate 120 instead of a conventional closed loop direct pressure measurement type of control enables more accurate and precise exertion of pressure to the surface 120a of the substrate 120 by the cleaning pad 311. The desired amount of down force and/or pressure that is applied by the cleaning pad 311 as a function of the distance the pad carrier 307 and cleaning pad 311 travelled after the cleaning pad 311 contacts the surface of the substrate can be empirically determined or derived from modeling. The controller 160 will start measuring pad deformation in terms of the distance the cleaning pad 311 is driven into the substrate 120, or the cleaning distance. Using a known value of pad compression, in some embodiments, the controller 160 is then able to use pad material data to determine the amount of pressure and/or force the pad 311 is exerting on the substrate 120 based on the amount of pad 311 compression. These techniques enable very low pressures to be precisely and accurately applied by the cleaning pad 311. For example, the pad 311 may apply less than 1 psi, for example a pressure of 0.04 psi on a 134 mm diameter pad.

### Hydrodynamic Effect

It has been found that the combination of the pad 311 material, the ability to precisely control the position of the pad carrier 307 relative to the surface of the substrate 120, combined with the use of higher rotation speeds provided by the motors in the PC module 200 enable the creation of a hydrodynamic effect as the pad processing surface 311a translates across the surface of the substrate.

FIG. 6 illustrates a connection between the Stribeck curve, and the Hersey number for formations of hydrodynamic films. The Hershey number is a dimensionless number obtained from the velocity (m/s) times the dynamic viscosity (Pa·s=N·s/m²), divided by the load per unit length of bearing (N/m) and relates to friction coefficients μ when the height of a hydrodynamic film is at least 50 times greater than the dimensions of the molecules in the fluid 321. Very thin films have higher viscosities and when the fluid films are about 5 nm in size, the film can display solid properties, aiding in the cleaning process. The Stribeck curve show in the graph of FIG. 6 is the frictional characteristics of a liquid over conditions usually spanning the boundary between mixed and hydrodynamic regimes. The three regimes from left to right are the direct contact regime, the mixed lubrication regime and the hydrodynamic regime. Each regime is defined by a Hersey number, which can be determined using various techniques (e.g., See also ASTM D2266). This measurement concept was discussed in Hersey, Mayo, The Laws of Lubrication of Horizontal Journal Bearings, Journal of the Washington Academy of Sciences, 4, 1914.

As illustrated in FIG. 6, the horizontal axis (h) is the Hersey number. The Hersey number is related to the height of a film between an elastic solid and a rigid solid. The force applied to the pad 311 is important to determine an accurate and precise Hersey number. For example, the rigid solid may be the substrate 120, the elastic solid may be a PVA pad, and the film height may be the film formed within the interaction between the fluid 321, the pad 311, and the substrate 120. Not being bound by theory, using the spring constant of the pad material and the deformation of the pad, can produce the load applied to the pad 311 with more precision than just a pressure sensor alone. Knowing the precise pressure exerted by the pad 311 ensures that an accurate Hersey number can be identified and operating conditions can be maintained at the proper position along the Stribeck curve. The formulated Hersey number can be used to identify process parameters that ensure the Hersey number stays for example between 1 and 10.

FIG. 5 is a flow diagram illustrating a polishing process 500 according to embodiments of the present disclosure. The process 500 may be performed in a PC module, such as the PC module 200 that is controlled by a system controller, such as the system controller 160. The process 500 starts, at operation 502, with the controller 160 causing fluid 321 to be flowed to the pad processing surface 311a of the pad 311 and the substrate surface 120a of a substrate 120 disposed on the rotatable substrate table 230 via the nozzle(s) 314. The fluid 321 may be configured to clean or polish the substrate 120, for example a substrate having a copper layer disposed thereon. Once the system controller 160 has started flowing fluid 321 to the substrate surface 120a, the pad 311 is rotated by the pad motor 308 attached to the pad carrier 307. The system controller 160 communicates to the pad motor 308, the speed the pad 311 is to be rotated and controls the rotation accordingly. The system controller 160 reads the initial torque value from the pad motor 308 prior to lowering the pad 311 to the substrate surface 120a.

Once the initial torque value is established, at operation 504, the controller 160 causes the lift actuator assembly 302 and lift mechanism 305 to lower the pad 311 via the pad carrier 307. While the pad 311 is rotating the controller is waiting to detect a contact torque value generated by the pad motor 308 when the pad processing surface 311a comes into contact with the substrate surface 120a. The contact torque value will occur at the contact point, which is defined by the gap formed between the pad processing surface 311a and the substrate supporting surface 230a of the rotatable substrate table 230.

Then, at operation 506, the controller 160 causes the pad carrier 307 and cleaning pad 311 to be driven further toward the substrate 120 by a cleaning distance compressing the pad 311. The cleaning distance is generally defined as the pad compression or pad deformation as the pad 311 is driven into the substrate surface 120a. It has been found that the actual pressure the pad 311 exerts on the substrate 120 is more accurately identified using a look-up in a data table or by use of an empirically derived equation utilized by the system controller 160, than by a pressure sensor alone. The precise control of the cleaning distance is used to accurately control the amount of pressure applied to the surface of the substrate 120a in low pressure applications because of the elastic nature of the cleaning pads 311. The interaction between the fluid 321, the rotation of the pad processing surface 311a, and the substrate surface 120a creates a cleaning torque that can be measured on the pad motor 308. The cleaning torque will vary as a function of height H. Once the cleaning pad 311 has traveled the cleaning distance, the PC module 200 performs a cleaning operation 508 in which the cleaning pad 311, which is positioned at the angle θ relative to the surface of the substrate 120, is translated across the surface of the substrate in an arcuate motion by use of the column motor 315, while the fluid 321 is provided to the surface of the substrate 120a and the pad processing surface 311a of the cleaning pad 311. The cleaning torque is monitored during processing to ensure the consistent operation, such that if a deviation occurs in the torque value seen by the controller 160, it will signal an error has occurred. The process is over once the substrate 120 is cleaned and the pad is raised at operation 510.

According to some embodiments of the flow diagram in FIG. 5, a method of cleaning a substrate 120, includes placing a substrate 120 in a pre-clean module 200, rotating the substrate table 230 and delivering a fluid 321 towards the substrate supporting surface 230a of the substrate table 230. The method further includes, rotating the pad 311 at a predetermined cleaning speed and sensing an initial torque value with the controller 160 generated by the pad motor 308. The pad 311 is then lowered by the lift actuator assembly 302, until the controller 160 senses a contact torque generated by the pad motor 308 at the contact point formed at an increase in torque, but prior to cleaning pad 311 compression. The cleaning pad 311 is then moved a cleaning distance towards the substrate supporting surface 230a, compressing the pad by the cleaning distance. The pad 311 is then translated across the substrate supporting surface 230a.

The embodiments disclosed herein enable precise pressure control and the creation of the hydrodynamic effect that may include a hydrodynamic film at the interaction of the pad 311 and the substrate 120. It is believed that the hydrodynamic film minimizes the number of scratches generated at the substrate surface 120a. This effect is specifically useful for cleaning and polishing substrates with metal containing and/or delicate surfaces, for example substrates with copper (Cu) surfaces. In addition to creating a hydrodynamic effect, benefits described herein include holding the pad 311 at the angle θ and/or the use of pad features 401 further enabling the pad 311 to recharge itself with fluid 321. The angle and the features ensure the pad 311 is constantly full of fluid and maintaining the hydrodynamic effect. These features alone and/or in combination have shown the surprising benefit of improved cleaning operations with less damage to the surface of the substrate 120a. The improvements described herein can also be applied to substrates with sensitive coatings, for example substrates with copper coatings. Another example of a benefit is the improvement in the process of removing of metals, metal oxides, and polishing slurry from the substrate surface 120a in cleaning operations that follow polishing operations and/or that follow operations that use abrasives mixed into a slurry.

While the foregoing is directed to implementations of the present disclosure, other and further implementations of the disclosure may be devised without departing from the basic scope thereof, and the scope thereof is determined by the claims that follow.

What is claimed is:

1. A method of cleaning a substrate, comprising:
rotating, by use of a first motor, a substrate table and delivering a fluid to a surface of a substrate positioned on supporting surface of the substrate table of a cleaning module;
rotating a cleaning pad at a cleaning speed, and sensing, by use of a controller, an initial torque value generated by a second motor;
lowering the cleaning pad, by use of a lift actuator assembly, until the controller senses a contact torque generated by the second motor when a pad processing surface of the cleaning pad contacts a surface of the substrate, wherein the pad processing surface contacts the surface of the substrate at a contact point;
translating, by a command from the controller, the cleaning pad a cleaning distance towards the substrate, wherein the cleaning pad is compressed by the translation of the cleaning pad the cleaning distance; and
translating the pad processing surface of the cleaning pad across the substrate supporting surface.

2. The method of claim 1, wherein a pressure experienced by the cleaning pad to the surface of the substrate is below at least 0.5 PSI.

3. The method of claim 1, wherein a hydrodynamic film is formed at the pad processing surface of the cleaning pad.

4. The method of claim 1, further comprising calculating a force applied to the cleaning pad based on a pad compression.

5. The method of claim 1, wherein the cleaning pad comprises a polyvinyl alcohol (PVA) material.

6. The method of claim 1, wherein the cleaning speed is between about 750 RPM to about 2500 RPM.

7. A pre-clean module for cleaning a substrate, comprising:
a rotatable substrate table having a substrate supporting surface for supporting a substrate thereon;
a pad carrier assembly, the pad carrier assembly comprising:
a carrier column;
a carrier arm coupled to the carrier column, extending radially outward from an axis of the carrier column;
a lift mechanism coupled to the carrier arm;
a lift actuator assembly coupled to the carrier arm and in mechanical communication with the lift mechanism; and
a pad carrier configured to be raised and lowered by the lift mechanism and the lift actuator assembly with respect to the surface of the substrate table, the pad carrier comprising:
a cleaning pad;
a pad motor configured to rotate the cleaning pad about a central motor axis; and
a shaft that couples the pad motor to the cleaning pad; and
a system controller configured to determine a pad compression.

8. The pre-clean module of claim 7, wherein the pad carrier is configured such that the central motor axis is at an angle with respect to a vertical axis of the pad carrier.

9. The pre-clean module of claim 8, wherein the angle is between about 0.01° and about 6°.

10. The pre-clean module of claim 7, wherein the cleaning pad comprises a polyvinyl alcohol (PVA) material.

11. The pre-clean module of claim 7, wherein a pad processing surface of the cleaning pad includes a plurality of polishing features.

12. The pre-clean module of claim 11, wherein the polishing features comprise a plurality of mesas disposed in a radial pattern extending from a surface of the pad.

13. The pre-clean module of claim 11, wherein the polishing features comprise a plurality of spokes disposed in a radial pattern extending from a surface of the pad.

14. The pre-clean module of claim 7, wherein the system controller is configured to read the pad compression with precision to about +/−10 micrometers (μm) to about +/−40 μm and able to determine an applied pressure from a compression reference with an accuracy of +/−0.04 psi.

15. A pre-clean module, comprising:
a rotatable substrate table having a substrate supporting surface for supporting a substrate thereon;
a system controller configured to calculate a force applied to a pad based on a compression of a pad;
a pad carrier assembly, the pad carrier assembly comprising:
a carrier arm;
a lift mechanism coupled to the carrier arm;
a lift actuator assembly coupled to the carrier arm and in mechanical communication with the lift mechanism, wherein the lift actuator assembly is configured to apply less than 30 N and is controlled by the system controller;
a pad carrier configured to be moved by the lift mechanism and lift actuator assembly, the pad carrier comprising:
a pad motor capable of sensing and communicating a real time experienced torque value;
a shaft; and
a pad coupled to the pad motor by the shaft, the pad comprising a PVA material.

16. The pre-clean module of claim 15, wherein the cleaning pad further comprises a pad pattern.

17. The pre-clean module of claim 16, wherein the pad pattern is a radial spokes pattern.

18. The pre-clean module of claim 15, wherein a pad processing surface is at an angle.

19. The pre-clean module of claim 18, wherein the pad processing surface is angled between about 1° and about 5°.

20. The pre-clean module of claim 15, wherein the pad motor is capable of rotating the pad between about 750 to about 2500 RPM.
